(19) United States
(12) Patent Application Publication
(10) Pub. No.: US 2014/0085706 A1
(43) Pub. Date: Mar. 27, 2014

(54) POLYCHROME ELECTROPHORETIC INK, ASSOCIATED DISPLAY DEVICE AND MANUFACTURING PROCESS

(71) Applicants: ARKEMA FRANCE, Colombes (FR); CENTRE NATIONAL DE LA RECHERCHE SCINETIFIQUE, Parie Cedex (FR); UNIVERSITE DE BORDEAUX 1, Talence (FR); INSITITUT POLYTECHNIQUE DE BORDEAUX, Talence Cedex (FR)

(72) Inventors: Cyril Brochon, Merignac (FR); Georges Hadziioannou, Leognan (FR); Antoine Charbonnier, Bordeaux (FR)

(73) Assignees: ARKEMA FRANCE, Colombes (FR); CENTRE NATIONAL DE LA RECHERCHE SCINETIFIQUE, Parie Cedex 14 (FR); UNIVERSITE DE BORDEAUX 1, Talence (FR); INSITITUT POLYTECHNIQUE DE BORDEAUX, Talence Cedex (FR)

(21) Appl. No.: 13/978,029

(22) PCT Filed: Oct. 9, 2012
(86) PCT No.: PCT/FR2012/052284

§ 371 Date: Aug. 30, 2013

(30) Foreign Application Priority Data
Oct. 10, 2011 (FR) 11.59109

(51) Int. Cl. G02F 1/167; G03G 9/06; H05K 13/00

(52) U.S. Cl. CPC G02F 1/167; H05K 13/00; G03G 9/06
USPC 359/296; 427/58; 430/32

(57) ABSTRACT

A polychrome electrophoretic ink including at least four types of particles dispersed in a nonpolar organic medium, each particle type containing a pigment of a color which is associated therewith, having a positive or negative electrostatic charge, characterized in that at least one of the abovementioned particle types has a magnetic property (magnetic core) such that each particle type can migrate in a predetermined manner under the combined action of an electrostatic force and of a magnetic return force.

### CROSS REFERENCE TO RELATED APPLICATIONS

The present application is a National Stage of International Application No. PCT/FR2012/052284, filed on Oct. 9, 2012, which claims priority of French Application No. 11.59109, filed on Oct. 10, 2011. The entire contents of each of International Application No. PCT/FR2012/052284 and French Application No. 11.59109 are hereby incorporated herein by reference in their entirety.

### FIELD OF INVENTION

The present invention relates to the field of inks for electrophoretic display devices, and more particularly of polychrome inks.

More specifically, the invention relates to a polychrome electrophoretic ink, to a process for manufacturing said ink, to a polychrome electrophoretic display device comprising said ink and to the use of said polychrome electrophoretic ink for producing a polychrome electrophoretic display device.

### BACKGROUND

There are currently essentially two modes of information display. There are, on the one hand, electronic displays of liquid crystal LCD (acronym for “Liquid Crystal Display”) type or of plasma type for example, and, on the other hand, displays by printing on a paper support. Electronic displays have a big advantage since they are capable of rapidly updating displayed information and therefore of changing content, they are also said to be rewritable. This type of display is, however, complex to produce since the manufacturing thereof requires working in a clean room and high-tech electronics. It is consequently relatively expensive. Displays made by printing on a paper support, for their part, can be produced in bulk since they are very inexpensive, but do not allow information to be rewritten over the previous information. This type of display belongs to non-rewritable displays.

The idea of being able to combine the advantages of the two technologies arose a few years ago. A flexible display which can be manufactured at low cost and in great volume was produced. This display is the analog of paper but in an electronic version, i.e. the information displayed on this support can be erased so as to rapidly leave room for another content. Furthermore, unlike the existing screens which need to always have a power supply in order to be able to operate, electronic paper consumes only a very small amount of energy, only at the time the display changes. At a time when energy consumption is a major problem, having a flexible, reusable display device which mimics paper and consumes virtually no energy is a great opportunity. Furthermore, electronic paper is a reflective device, hence a much increased reading comfort compared with screens with back-lighting which considerably tire the eyes. This type of display is based on EPIDS (acronym for “ElectroPhoretic Image DisplayS”) technology. This technology consists in dispersing charged particles in a nonconductive medium between two parallel electrodes. More specifically, the display comprises a conductive surface electrode, a cavity comprising pixels filled with electrophoretic ink, and a bottom electrode connected to transistors for controlling each pixel. The pixels can be produced in various ways. They can, for example, be produced by means of a grid which partitions the cavity into as many pixels as are necessary for producing the display, or else they can be in the form of microcapsules, each microcapsule defining a pixel and being filled with said ink. The electrophoretic ink comprises generally white, negatively charged nanoparticles immersed in a black dye. When an electric field is applied, the white nanoparticles of each pixel will migrate to either of the electrodes. Thus, when a negative electric field is applied, the white nanoparticles place themselves at one end of the pixel, revealing their white color or the color of the black dye depending on their position relative to the surface of the display. Consequently, by placing millions of pixels in the cavity of the display and by controlling them with electric fields, by means of an electronic circuit intended to manage the displaying of the information, it is possible to generate a two-color image. One of the advantages of this type of display is that the contrast obtained depends directly on the migration of the nanoparticles and on the color thereof. Furthermore, the display obtained is bistable since the image remains in place even once the electric field has been turned off. Such displays based on EPIDS technology are in particular envisioned for equipping cell phones, electronic tablets, electronic books or else on-board displays on chip cards for example.

However, although they have many advantages, screens based on EPIDS technology currently enable only two-color information to be displayed. In order to be able to use this technology for the screens of cell phones, of tablets or of electronic books, it becomes important to improve this display and to propose a polychrome display, in order to be competitive in the screen market.

Tests have been carried out in order to produce such screens capable of displaying information in color. Such a color display is based on three different principles: the setting up of a matrix of colored filters above a two-color device, as in particular described in patent U.S. Pat. No. 7,289,101, the juxtaposition of two-color pixels displaying different colors, and, finally, the semi-selective migration of pigments based on a variation in the charge level of the particles and therefore on a variation in their electrophoretic mobility.

However, such displays remain quite complex to produce and the display obtained does not offer a great contrast, so that the reading comfort is as a result greatly reduced.

The article entitled “Pigment-based tricolor ink particles via mini-emulsion polymerization for chromatic electrophoretic displays”, published in 2010, in particular by Mr Ting Wen, is also known. That article describes the synthesis of charged colored particles via a mini-emulsion polymerization technique, but does not in any way provide for the use of magnetic properties in the particles synthesized. It should also be noted that, in that article, the polymer used is styrene, i.e. a nonfunctional polymer, and the charge is introduced by an additive. Finally, the technology envisioned with the synthesis of such particles is that of obtaining the color by juxtaposition of pixels each containing only two types of positive and negative particles, which consists of the juxtaposition of conventional electrophoretic cells.

In addition, the article entitled “Towards Multi-color Microencapsulated Electrophoretic Display”, published in 2005, in particular by Mr Chul Am Kim, is also known. That article describes the synthesis of a simple white particle which is negatively charged with methacrylic acid by dispersion polymerization in methanol, and neither discloses nor even suggests the use of magnetic properties in the particles synthesized.

### SUMMARY

In this context favorable for the development of display means based on EPIDS technology, the production of new inks enabling a polychrome display becomes essential for increasing the performance level of such devices and therefore for increasing their competitiveness in the market. The purpose of the invention is therefore to remedy at least one of the prior art drawbacks. The invention aims in particular to synthesize an electrophoretic ink comprising several pigments of different color.

### BRIEF DESCRIPTION OF THE DRAWING

FIG. 1 shows a simplified diagram of four juxtaposed pixels of a display, in which the four types of different particles making up the polychrome electrophoretic ink are diagrammatically represented.

### DETAILED DESCRIPTION

To this effect, the subject of the invention is a polychrome electrophoretic ink comprising at least four types of particles dispersed in a nonpolar organic medium, each particle type containing a pigment of a color which is associated therewith, having a positive of negative electrostatic charge, characterized in that at least one of the abovementioned particle types has a magnetic property (magnetic core) such that each particle type can migrate in a predetermined manner under the combined action of an electrostatic force and of a magnetic return force.

Thus, by mixing particles having pigments of different colors, each particle of a color having a magnetic and electrostatic characteristic which is specific thereto, it becomes possible to cause one or more of these particles to migrate in the ink, according to the magnetic force and the electrostatic force which is applied thereto at the level of each pixel. According to their migration, the colored particles are superimposed, so that they thus make it possible to display polychromic information.

Preferably, the ink comprises at least two types of particles with a magnetic core and two types of nonmagnetic particles. The two types of particles with a magnetic core are also respectively positively and negatively electrostatically charged. Likewise, the two types of nonmagnetic particles are also respectively positively and negatively electrostatically charged.

Thus, in order to make a nonmagnetic particle migrate, for example, toward either of the electrodes of an electrophoretic display, it is necessary to apply a positive or negative voltage at the edges of the electrodes, according to its electrostatic charge. The voltage applied will be denoted V+ or V−. In order to cause a magnetic particle to migrate, it will also be necessary to apply, at the edges of the electrodes, a positive or negative voltage according to its charge, but this voltage must be greater than that applied for moving a nonmagnetic particle since it must, in addition, overcome a magnetic return force applied to the particle. The voltage applied, for causing such a magnetic particle to migrate, will be denoted V++ or V−−.

The two types of particles with a magnetic core are each associated with a color. Each magnetic core is covered with the pigment which is associated therewith, and then encapsulated in a functional polymer which is respectively positively and negatively electrostatically chargeable. Likewise, each nonmagnetic particle type is associated with a color. The pigment chosen for a nonmagnetic particle type is encapsulated in a functional polymer which is respectively positively and negatively electrostatically chargeable.

Preferably, three of the types of particles each contain a pigment such that, depending on their migration, said three types of particles are capable of displaying the colors of the RGB system (acronym to denote the “Red Green Blue” additive synthesis system which is based on the three primary colors) or the colors of the CMY system (acronym to denote the “Cyan Magenta Yellow” subtractive synthesis system). The fourth particle type preferably contains a white-colored or black-colored pigment.

Among the pigments used for the various colors, use may, for example, be made of:
for red, hematite or cadmium red,
for green, cobalt green or chromium oxide,
for blue, copper silicate or cobalt blue,
for black, carbon black or magnetite.

This list of pigments is not exhaustive and any inorganic pigment (oxide, silicate, etc.) can be used provided that, in the end, the set of pigments used makes it possible to display the colors of the RGB system or of the CMY system and the color black. Furthermore, shades exist for certain pigments; for example, cobalt blue can come in several tones, from dark blue through to turquoise blue.

The process for manufacturing this polychrome electrophoretic ink consists in synthesizing each particle type separately in a nonpolar organic medium, such as an oil, or a nonpolar or barely polar organic solvent, for instance toluene or an alkane for example, and then in mixing them. In this case, the nonpolar organic medium, in which the syntheses of the various particles has taken place, advantageously constitutes the dispersant medium of the ink or, at the very least, it is compatible therewith.

With regard to the particles with a magnetic core, the syntheses thereof consist in covering a magnetic core with an inorganic pigment and then in encapsulating it in a chargeable functional polymer.

According to one possibility offered by the invention, the synthesis of the magnetic core consists in synthesizing magnetic particles which are stable in a nonpolar organic medium, and then in synthesizing a latex containing the magnetic core, by heterogeneous-medium polymerization techniques in polar or nonpolar organic or aqueous media, from a styrene or methyl methacrylate monomer.

In the context of the present invention, the term “latex” means a dispersion in a solvent of particles partially or completely made of polymer.

Advantageously, the magnetic particles synthesized or used are metal oxides.

In other words, a magnetic latex is first synthesized, then it is covered with a pigment and, finally, it is encapsulated in an electrostatically chargeable polymer shell.

The polymers forming the external shell have acid units (for the negative particles), or basic units (for the positive particles). Consequently, a simple acid-base reaction allows these units to pull off or capture a proton and therefore to acquire the respectively negative or positive charge desired. For the positive particles, instead of capturing a proton, it is also possible to make them capture any chemical group which can bond to a nitrogen acid of the basic units.

The magnetic latex, also referred to as magnetic core in the rest of the description, is manufactured in several steps. A first step consists in preparing an organic ferrofluid, according to a process known as the “Massart process”. This process consists in coprecipitating ferric chloride (FeCl₃) and ferrous chloride (FeCl₂) in an aqueous medium so as to form magnetite (Fe₃O₄). This coprecipitation takes place in a basic medium, in the presence of concentrated aqueous ammonia. Oleic acid then makes it possible to go from an aqueous ferrofluid to an organic-phase ferrofluid by grafting carbon-based chains at the surface of the magnetite nanoparticles.

A second step then consists in synthesizing a magnetic latex intended for encapsulating the magnetite obtained and in thus forming the core of the magnetic particle. For this, the magnetite synthesized in the first step is dispersed in hexadecane, which is a very hydrophobic agent, with styrene, which is the monomer used to encapsulate the magnetite. Sodium dodecyl sulfate (SDS), for example, is used as surfactant, and potassium persulfate is used as polymerization initiator. According to one implementation variant, nonionic surfactants, such as Tween 80 (Polysorbate 80) or Span 80 (sorbitan monooleate) can also be used.

A pigment is then precipitated onto the surface of this magnetic core, by hydrolysis of a precursor.

The encapsulation of this colored magnetic core, in a chargeable polymer, is then carried out. This step of encapsulating a colored magnetic particle consists in dispersing said colored magnetic particle in said nonpolar organic medium, then in synthesizing at least one polymer latex which is stable in said organic medium, said latex precipitating around said particle so as to form a protective shell, said synthesis of the latex being carried out by polymerization, in said organic medium, of an electrostatically chargeable functional monomer, employing combined use of a macroinitiator and of a coinitiator.

Likewise, with regard to the nonmagnetic particles, an associated pigment is encapsulated directly in a chargeable polymer according to the encapsulation process which has just been described.

Once the various types of particles have been synthesized separately, they are then mixed so as to obtain a polychrome electrophoretic ink. The ink thus manufactured is then used in particular for producing a polychrome electrophoretic display device.

The invention also relates to a polychrome electrophoretic display device comprising the ink which has just been described. This device comprises a conductive surface electrode, a cavity comprising cells filled with polychrome ink, each cell being in fluidic communication with its neighbor and defining a pixel, a bottom electrode comprising a contact spot under each pixel, each spot being connected to a transistor of an integrated circuit intended for controlling the application of an electrostatic force to each pixel, and, finally, a magnetic means capable of applying a magnetic return force to the particles with a magnetic core. The magnetic means can advantageously be chosen from the following elements: a magnetic strip, or an electromagnet for example.

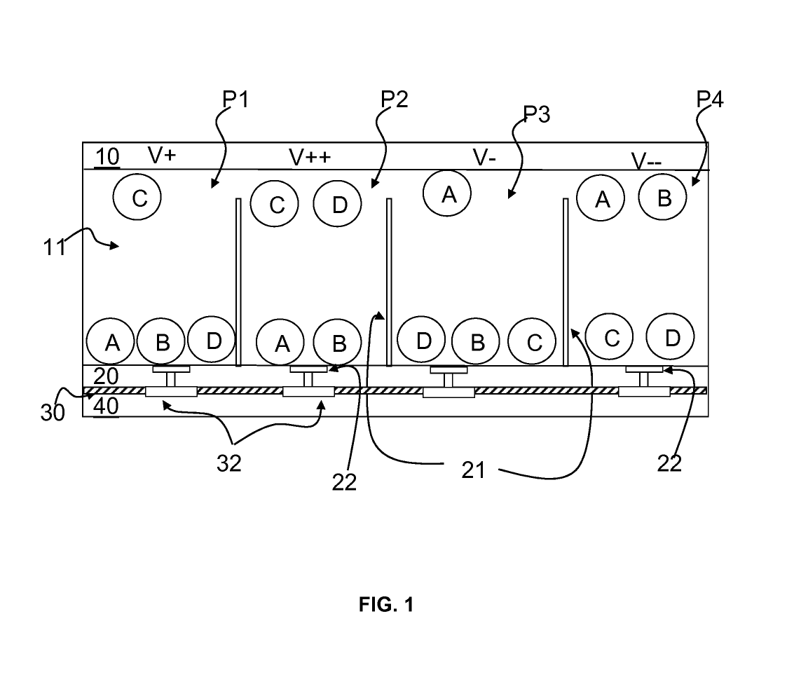

Other advantages and characteristics of the invention will emerge on reading the following examples given by way of illustrative and nonlimiting example, with reference to the appended FIG. 1 which represents a very simplified diagram of four juxtaposed pixels of a display, in which the four types of different particles making up the polychrome electrophoretic ink are diagrammatically represented.

Each pixel is controlled, on the one hand, by a magnetic force and, on the other hand, by a different electrostatic force, such that one or more different types of particles migrate toward the surface electrode in each of the pixels, in order to obtain a polychrome display.

### EXAMPLE 1

Synthesis of a White Particle with a Magnetic Core

The electrophoretic ink is manufactured by mixing all the types of particles obtained separately. The synthesis of a magnetic or nonmagnetic particle is based on one and the same process with more or fewer steps.

Described in this example is the synthesis of a white particle with a magnetic core. Of course, this synthesis can be carried out with any pigment so as to obtain the particle of desired color. Likewise, for the particles of nonmagnetic type, the first steps of the synthesis, consisting in preparing a magnetic core (steps 1 and 2), and then in covering it with a pigment (step 3), will not be reproduced.

### 1st Step: Preparation of an Organic Ferrofluid:

The synthesis of the ferrofluid is carried out according to a process known as the “Massart process”. This process consists in coprecipitating ferric chloride (FeCl₃) and ferrous chloride (FeCl₂) in an aqueous medium so as to obtain magnetite (Fe₃O₄). For this, 180 g of FeCl₂, 100 ml of HCl and 500 ml of water are mixed in a beaker. Hydrochloric acid (HCl) is added at the beginning of the synthesis essentially in order to facilitate the dissolving of FeCl₂. While stirring rapidly, 370 ml of FeCl₃ are then added, followed by 2 l of water and the mixture is still stirred vigorously. However, this coprecipitation can only be carried out in a basic medium. Consequently, 1 l of concentrated aqueous ammonia is rapidly added all at once, and the mixture is left to stir for 30 minutes. After this period, an aqueous ferrofluid is obtained.

136 g of oleic acid are then added to the ferrofluid obtained, then the mixture is stirred at 70° C. for 30 min. The oleic acid in fact makes it possible to go from an aqueous-phase ferrofluid to an organic-phase ferrofluid by grafting carbon-based chains at the surface of the magnetite nanoparticles. The ferrofluid is then decanted, washed, and then redispersed in an organic phase in an alkane, such as octane or cyclohexane, for example.

### 2nd Step: Preparation of a Magnetic Latex

The magnetite obtained in the first step is then encapsulated in a polymer, in order to produce the magnetic core of the particles of magnetic-core type within the meaning of the invention. For this, 2 g of this magnetite obtained are dispersed in 6 g of styrene and 0.25 g of hexadecane. The whole mixture is subjected to ultrasound in order to thoroughly disperse the magnetite and to create a miniemulsion. The styrene is the monomer used to encapsulate the magnetite. The hexadecane is a very hydrophobic agent which makes it possible to produce the miniemulsion. 0.2 g of SDS (sodium dodecyl sulfate) is then dissolved in 25 g of water, in a beaker, and then the miniemulsion is added and the mixture is stirred for 20 minutes. SDS is a surfactant which makes it possible to thoroughly disperse the particles in the miniemulsion. The whole mixture is then subjected to ultrasound for 5 minutes in order to maintain good dispersion of the particles, and then 0.10 g of KPS (potassium persulfate) diluted in water is added. The KPS is in this case the polymerization initiator. The whole mixture is then heated for 12 h at 70° C. Throughout this time, a polymer precipitates and covers each magnetite particle. Magnetic latex particles, also called magnetic cores, are then obtained.

3rd Step: Coloration of the Magnetic Core with the Pigment

In this step, the magnetic latex obtained in the previous step is first dispersed in an alcoholic solvent, such as ethanol for example. A water/aqueous ammonia solution is then added to this mixture, then tetrabutyl titanate is dropped in over the course of approximately 1 h30 and the mixture is then left to stir for a further 2 h. The water/aqueous ammonia solution allows, in this case, the precursor (tetrabutyl titanate) to condense as titanium oxide (TiO₂) around the magnetic latex. The whole assembly obtained is then washed by means of centrifugation/redispersion cycles. At the end of these cycles, a magnetic latex coated with a white layer of titanium oxide is obtained.

Of course, this example is only an illustration and the magnetic latexes may be colored in any color through the use of appropriate pigments. Thus, for example, if it is desired to cover a magnetic latex with a layer yellow in color, for example with cadmium sulfide, this chromium oxide is precipitated on the magnetic core by hydrolysis of its precursor for example. The precursor of CdS is a solution of Cd²⁺ ions obtained from cadmium acetate in water, to which is added thioacetamide for. The precipitation of the yellow pigment takes place over time. In this case, there is no need to have a water/aqueous ammonia solution, the two reagents spontaneously reacting together. Be that as it may, the coloration of a magnetic latex with any pigment can be carried out according to the processes already known to those skilled in the art, by mixing the compounds which make it possible to precipitate the pigment at the surface of the magnetic latex.

When the magnetic core is colored, a final phase of the process for manufacturing the particle of magnetic type consists in encapsulating it in an electrostatically chargeable polymer.

Likewise, for the particles of nonmagnetic type, it is necessary to encapsulate the pigment chosen for such a particle in an electrostatically chargeable polymer shell.

For this, an intermediate step (the 4th step described below) consists in synthesizing a macroinitiator. This macroinitiator, used in combination with a coinitiator, would allow not only the polymerization of the polymer shell around the pigment, or the colored magnetic core depending on the type of particle, but also the stabilization of the particles thus synthesized in the nonpolar organic medium and the control of their sizes so that they are all homogeneous.

In the rest of the description, the term “coinitiator” or “initiator”, denotes without distinction an additive used to initiate a polymerization reaction. After the initiation of the polymerization reaction, the coinitiator forms a homopolymer which, via its precipitation, will be responsible for the particles and responsible for the enlarging thereof. Throughout the rest of the description, the coinitiator used is an initiator manufactured and sold by the company Arkema under the brand “Blockbuilder”.

The term “macroinitiator” denotes an additive composed of a hydrophobic polymer chain, serving to stabilize the particles, and of an initiator part which serves to initiate the polymerization reaction and results, in the end, in the formation of a copolymer. In the rest of the description, in order to clearly differentiate the hydrophobic polymer chain serving to stabilize the particles, it is denoted by the term “steric repulsion hair”. The macroinitiator is advantageously synthesized from the coinitiator. Consequently, the initiator part of the macroinitiator is identical to the coinitiator. The macroinitiator and the coinitiator both initiate in parallel the polymerization reaction of a functional monomer. At the end of the polymerization reaction, a copolymer is formed which comprises a newly formed polymer chain at the end of the steric repulsion hair and which is anchored in the particle. Thus, the steric repulsion hair remains attached to the particle and can thus stabilize it in the nonpolar organic medium.

The coinitiator, itself, serves just to initiate the reaction and produces only a homopolymer. The combination of these two initiators in appropriate proportions makes it possible to precisely control the size of the latex particles that will be obtained at the end. Indeed, the proportion between the two types of initiators will influence the homopolymer-to-copolymer ratio and thus the size of the particles obtained.

### 4th Step: Synthesis of a Macroinitiator for the Final Step of Organic-Dispersion Polymerization

1.33 g of coinitiator and 26.10 g of 2-ethylhexyl acrylate are mixed in 30 ml of toluene, in a 100 ml round-bottomed flask. The solution is stirred until it is homogeneous. Vacuum/nitrogen cycles are then carried out with stirring in order to remove all the dissolved gases. The round-bottomed flask is then heated at 120° C. for 2 h with stirring and then cooled in a bath of cold water. The macroinitiator thus formed is precipitated from methanol in order to purify it from the remaining monomer. The viscose liquid obtained is then dried under vacuum at 50° C. in order to remove the solvent remains. The macroinitiator thus synthesized is ready to be used for the subsequent step of encapsulation of the pigment or of the colored magnetic core depending on the type of particle to be encapsulated.

### 5th Step: Synthesis of the Final Particle

3 g of the particles previously synthesized, i.e., depending on the types of final particles to be synthesized, either the colored magnetic cores or the inorganic pigments, and 4 g of Span 80 (sorbitan monooleate) are mixed in 200 ml of toluene, in a 250 ml beaker. Span 80 is the surfactant which enables a better dispersion of the colored magnetic particles or of the inorganic pigments in the nonpolar organic solvent used (in this case, toluene). The mixture is stirred for 5 min until the Span 80 has completely dissolved, and then the mixture is subjected to ultrasound in order to thoroughly disperse the particles to be encapsulated. For this, use is made of an ultrasound probe of which the power is adjusted to approximately 420 W for 8 min, with alternation of a 2 s pulse and 2 s resting. During this sonication, the beaker containing the suspension is placed in a bath of cold water in order to prevent the temperature of the organic medium from increasing.

At the same time, 0.2 g of macroinitiator and 0.5 mg of coinitiator are dissolved in 5 ml of toluene. 5 ml of 4-vinylpyridine to be added are also prepared. The 4-vinylpyridine is one of the monomers which makes it possible to form the polymer shell around the inorganic pigments or the colored magnetic cores. This shell may then be positively charged (in the case of 4-vinylpyridine) or negatively charged (if an acid monomer of the type acrylic acid, methacrylic acid or derivatives thereof, which may or may not be copolymerized, is used). As soon as the sonication is finished, the dispersion of particles is immediately poured into a 250 ml reactor with mechanical stirring at 300 revolutions per minute. The mixture of macroinitiator and coinitiator dissolved in toluene, and then the 4-vinylpyridine, are then added to the reactor and the whole mixture is heated at 120° C. for 12 h under nitrogen sweeping. The white magnetic particles thus synthesized are subsequently recovered and are then purified by centrifugation/redispersion at 3000 revolutions per minute in toluene. This centrifugation step makes it possible to retain only particles of homogeneous size. Another way to recover particles of homogeneous size consists in carrying out a dialysis.

The functional monomers intended for forming the electrostatically chargeable polymer shell are chosen according to the final charge that the particle will have to carry. Thus, in order to have positively charged particles, for example, the functional polymer covering the pigments is formed from monomers of 4-vinylpyridine, or dimethylamino methacrylate-co-styrene for example. In order to have negatively charged particles, the functional polymer covering the pigments is formed from an acrylic acid, or methacrylic acid, and its derivatives, which may or may not be copolymerized, with another neutral monomer such as styrene or MMA (methyl methacrylate).

The method makes it possible to obtain latex particles having a size of between 50 nm and 50 μm. Below 50 nm, there is a risk of having polymer chains which are too short and which will not precipitate and therefore not form particles.

The size of the particles, for the intended application, is preferably between 0.5 and 2 μm.

Advantageously, the choice of the size is obtained by varying the percentage of coinitiator relative to the percentage of macroinitiator at a fixed monomer content. The macroinitiator/coinitiator molar ratio for the intended application is preferably between 2.5 and 30. In practice, when the molar concentration of coinitiator relative to the molar concentration of macroinitiator is increased, the size of the particles is increased, and vice versa.

The polymer shell charges itself in the presence of an appropriate compound. The polymers forming the external shell have either acid units (for the negative particles) or basic units (for the positive particles). Therefore, a simple acid-base reaction allows these units to pull off or capture a proton and therefore to acquire the charge. For the positive particles, instead of capturing a proton, it is also possible to make them capture any chemical group which can bond to a nitrogen atom of the basic units. This is, for example, what happens when the white particles thus synthesized are placed in the presence of iodomethane: the particles become positively charged.

For the synthesis of the nonmagnetic particles, only steps 4 and 5 are carried out, i.e. the synthesis of the macroinitiator required for step 5 of encapsulation of an inorganic pigment. The inorganic pigment is dispersed beforehand in the nonpolar organic medium by virtue of a surface treatment or a surfactant. The surface treatment can, for example, consist in grafting carbon-based chains onto the hydroxyl groups of the pigment in order to increase its hydrophobicity. Once the surface modification has been carried out, ultrasound is used for 5 to 10 minutes in order to disperse the pigment.

According to one implementation variant, a surfactant such as sorbitan monooleate (Span 80) is used, so as to modify the surface tension of the pigment. The inorganic pigment is then dispersed in the nonpolar organic medium by means of ultrasound for 5 to 10 minutes.

Once all the types of particles have been manufactured separately according to the process which has just been described, they are mixed so as to form the polychrome ink which will be poured into the pixels of an electrophoretic display.

### EXAMPLE 2

Synthesis of a Black Particle with a Magnetic Core

The products used for this synthesis are the following: a magnetite Fe₃O₄ black pigment, Span 80 (sorbitan monooleate) as surfactant for enabling good dispersion of the pigment particles in the nonpolar solvent, the coinitiator sold by the company Arkema under the brand “Blockbuilder”, 2-ethylhexyl acrylate intended to be used for the synthesis of the macroinitiator, 4-vinylpyridine which is the monomer intended for forming the positively charged polymer shell encapsulating the black pigment, and toluene as nonpolar solvent. The 2-ethylhexyl acrylate and 4-vinylpyridine monomers are purified beforehand on a drying agent, such as calcium hydride CaH₂, and distilled under reduced pressure in order to remove any residual inhibitor.

1st step: Synthesis of the Macroinitiator:

1.33 g of coinitiator and 26.10 g of 2-ethylhexyl acrylate are mixed in 30 ml of toluene, in a 100 ml round-bottomed flask. The solution is stirred until it is homogeneous. Vacuum/nitrogen cycles are then carried out with stirring in order to remove all the dissolved gases. The round-bottomed flask is then heated at 120° C. for 2 h with stirring and then cooled in a bath of cold water. The macroinitiator thus formed is precipitated from methanol in order to purify it from the remaining monomer. The viscose liquid obtained is then dried under vacuum at 50° C. in order to remove the solvent remains. The macroinitiator thus synthesized is ready to be used for the subsequent step of encapsulation of the pigment.

### 2nd Step: Encapsulation of the Fe₃O₄ Pigment by Dispersion Polymerization

3 g of Fe₃O₄ and 4 g of Span 80 (sorbitan monooleate) are mixed in 200 ml of toluene, in a 250 ml beaker. Span 80 is the surfactant which allows better dispersion of the pigment particles in the nonpolar organic solvent. The solution is stirred for approximately 5 min until the Span 80 has completely dissolved, and then the mixture is subjected to ultrasound in order to thoroughly disperse the pigment particles. For this, use is made of an ultrasound probe of which the power is adjusted to approximately 420 W (Watts) for 8 min, with alternation of a 2 s (second) pulse and 2 s resting. During this sonication, the beaker containing the suspension is placed in a bath of cold water in order to prevent the temperature of the organic medium from increasing.

At the same time, 0.2 g of macroinitiator and 0.5 mg of coinitiator are dissolved in 5 ml of toluene. 5 ml of 4-vinylpyridine to be added are also prepared. As soon as the sonication has finished, the dispersion of Fe₃O₄ is immediately poured into a 250 ml reactor with mechanical stirring at 300 revolutions per minute. The mixture of macroinitiator and coinitiator dissolved in toluene, and then the 4-vinylpyridine, are then added to the reactor and the whole mixture is heated at 120° C. for 12 h under nitrogen sweeping. The 4-vinylpyridine is the monomer which will form the polymer shell around the pigment and which it will subsequently be possible to positively charge.

The black particles thus synthesized are subsequently recovered and are then purified by centrifugation/redispersion at 3000 revolutions per minute in toluene. This centrifugation step makes it possible to retain only particles of homogeneous size. Another way to recover particles of homogeneous size consists in carrying out a dialysis.

The black particles synthesized in the way described in the exemplary embodiment are then positively charged in the presence of iodomethane, for example, or on contact with other particles having acid groups. Positively charged, magnetic black particles are thus obtained.

### EXAMPLE 3

### Display Device Comprising the Polychrome Electrophoretic Ink

Represented diagrammatically in FIG. 1 are four pixels, referenced respectively P1, P2, P3 and P4, of a display device. The display device comprises a transparent surface electrode referenced 10, covering all the pixels. It also comprises a bottom electrode referenced 20. Between the two electrodes, a cavity 11 is made and filled with the polychrome electrophoretic ink. In fact, the cavity comprises cells which communicate with one another. These cells are delimited, on the one hand, by vertical walls 21, perpendicular to the bottom electrode 20, and, on the other hand, by the bottom electrode 20. These cells in fact define the pixels P1 to P4 of the display. They communicate with one another so as to allow the ink to flow freely and to fill all the cells. The bottom electrode 20 comprises contact spots 22. There is in fact a contact spot under each cell or pixel, each spot 22 being connected to a transistor 32 of an integrated circuit 30 intended for controlling the application of a different electrostatic force to each pixel. Finally, a magnetic means referenced 40 is placed under the bottom electrode 20. This magnetic means 40 can, for example, be in the form of a magnetic strip or of an electromagnet, for example.

The ink filling each of the pixels P1 to P4 is represented by four types of particles of which it is composed, these particles being respectively referenced A, B, C and D. In this illustrative but in no way limiting example, the particle A is, for example, blue in color, nonmagnetic and positively charged, the particle B is, for example, yellow in color, with a magnetic core and positively charged, the particle C is red, nonmagnetic and negatively charged, and, finally, the particle D is black in color, with a magnetic core and negatively charged.

Each of the particles with a magnetic core, i.e. the particles B and D in this example, is subjected to a magnetic return force induced by the magnetic strip or the electromagnet 40 placed at the bottom of the display device. Consequently, in order to cause the magnetic particles to migrate toward the surface electrode 10, it is necessary to increase the voltage applied between the electrodes relative to the voltage applied for moving particles of nonmagnetic type, in order to surpass this magnetic return force.

In the rest of the description, the voltage threshold required to move the nonmagnetic particles is denoted V+ (V−) and the voltage threshold required to move the magnetic particles is denoted V++ (V−−).

Thus, on the pixel P1, a voltage V+ is applied between the electrodes such that the nonmagnetic and negatively charged particle C moves toward the positive surface electrode 10. Consequently the pixel P1 displays the red color of the particle C. On the pixel P2, a voltage V++ is applied between the electrodes, such that the nonmagnetic and negatively charged particle C, and also the magnetic and negatively charged particle D, migrate toward the positive surface electrode 10. Consequently, the red and black colors of the two particles C and D are superposed at the surface of the pixel P2, such that the latter displays a black color. On the pixel P3, a voltage V− is applied between the electrodes such that the nonmagnetic and positively charged particle A migrates toward the negatively charged surface electrode 10. The pixel P3 therefore appears blue in the color of the particle A. Finally, on the pixel P4, a voltage V−− is applied such that the nonmagnetic and positively charged particle A, and also the magnetic and positively charged particle B, migrate toward the negatively charged surface electrode 10. Consequently, the blue and yellow colors of the particles A and B are superimposed at the surface of the pixel P4 so that the latter displays a green color.

The case which has just been described is merely an illustrative example to explain how a polychrome display containing such an ink operates. The colors displayed will depend on the choice of the colored particles which will be magnetic or nonmagnetic and negatively or positively charged. Furthermore, the particles of which the ink is composed are preferably chosen such that, depending on their migration in the pixels, they can display the colors of the RGB system or of the CMY system and the color black. Of course, another color representation system could be chosen without departing from the context of the invention.

Since the pixels are very small and are very close together, the human eye does not have sufficient resolution to be able to distinguish them from one another; consequently, the colors displayed by 3 or 4 juxtaposed pixels appear, in addition, to the human eye, to be superimposed. Thus, the eye reconstitutes an entire range of colors with many shades. Thus, for example when looking at a set of pixels, each displaying the three primary colors of the RGB system, since the human eye superimposes them, it will see a white-colored spot displayed on the screen.

The polychrome ink thus synthesized has many advantages. It is in particular a single ink, capable of displaying at least the three colors of the RGB (red-green-blue) system which are required for the production of polychrome display devices. By virtue of this ink, there is no loss of contrast compared with the displays using filters or using juxtaposition of two-color pixels, which can, in certain cases, lose between 50% and 75% of the maximum contrast. This is made possible by the fact that each pixel can display all colors.

Another advantage lies in the process for producing the color display device itself. Indeed, no control of the level of filling of the pixels with the ink is necessary because it is a single ink.

1. A polychrome electrophoretic ink comprising at least four types of particles dispersed in a nonpolar organic medium, each particle type containing a pigment of a color which is associated therewith, having a positive or negative electrostatic charge, wherein at least one of the abovementioned particle types has a magnetic property (magnetic core) such that each particle type can migrate in a predetermined manner under the combined action of an electrostatic force and of a magnetic return force.

2. The polychrome electrophoretic ink as claimed in claim 1, wherein the ink comprises two types of particles with a magnetic core, and wherein, for each, said magnetic core is covered with a pigment of a color which is associated therewith, and then encapsulated in a respectively positively and negatively electrostatically chargeable functional polymer.

3. The polychrome electrophoretic ink as claimed in claim 1, wherein the ink comprises two types of nonmagnetic particles each comprising a pigment of a color which is associated therewith, encapsulated in a respectively positively and negatively electrostatically chargeable functional polymer.

4. The polychrome electrophoretic ink as claimed in claim 1, wherein three of the types of particles each contain a pigment such that, depending on their migration, said types of particles are capable of enabling the colors of the RGB system or of the CMY system to be displayed, and in that a fourth particle type contains a white or black pigment.

5. A process for manufacturing said polychrome electrophoretic ink as claimed in claim 1, wherein the ink consists of synthesizing each particle type separately, in a nonpolar organic medium, and then mixing them, said nonpolar organic medium then constituting the dispersant medium of the ink obtained.

6. The process as claimed in claim 5, wherein the synthesis of a particle with a magnetic core consists of synthesizing a magnetic core, covering the magnetic core with an inorganic pigment, and then encapsulating the covered magnetic core in a chargeable functional polymer.

7. The process as claimed in claim 6, wherein the synthesis of the magnetic core consists of synthesizing magnetic particles which are stable in a nonpolar organic medium, then synthesizing a latex containing the magnetic core, by heterogeneous-medium polymerization techniques in polar or nonpolar organic or aqueous media, from a styrene or methyl methacrylate monomer.

8. The process as claimed in claim 7, wherein the magnetic particles synthesized or used are metal oxides.

9. The process as claimed in claim 5, wherein the synthesis of a nonmagnetic particle consists of encapsulating an inorganic pigment in a chargeable functional polymer.

10. The process as claimed in claim 6, wherein the step of encapsulation of a colored magnetic core or of an inorganic pigment consists of dispersing said colored magnetic core or said pigment in said nonpolar organic medium, then synthesizing at least one polymer latex which is stable in said organic medium, said latex precipitating around said colored magnetic core or said pigment, so as to form a protective shell, said synthesis of the latex being carried out by polymerization, in said organic medium, of an electrostatically chargeable functional monomer, employing combined use of a macroinitiator and of a coinitiator.

11. A polychrome electrophoretic display device comprising a polychrome electrophoretic ink as claimed in claim 1, wherein the device it comprises:
a surface electrode,
a cavity comprising cells filled with said polychrome electrophoretic ink, each cell being in fluidic communication with its neighbor and defining a pixel,
a bottom electrode comprising a contact spot under each pixel, each spot being connected to a transistor of an integrated circuit intended for controlling the application of an electrostatic force to each pixel,
a magnetic means capable of applying a magnetic return force to particles of magnetic-core type contained in each pixel.

12. The polychrome electrophoretic display device as claimed in claim 11, wherein said magnetic means is chosen from the following elements:
a magnetic strip or an electromagnet.

13. A method for producing a polychrome electrophoretic display device, the device comprising: a surface electrode; a cavity comprising cells, each cell being in fluidic communication with its neighbor and defining a pixel; a bottom electrode comprising a contact spot under each pixel, each spot being connected to a transistor of an integrated circuit intended for controlling the application of an electrostatic force to each pixel; and a magnetic means capable of applying a magnetic return force to particles of magnetic-core type contained in each pixel,
the method comprising filling each cell with the polychrome electrophoretic ink as claimed in claim 1.
